(19) United States
(12) Patent Application Publication
(10) Pub. No.: US 2024/0379865 A1
(43) Pub. Date: Nov. 14, 2024

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Ryo ONODERA, Tokyo (JP); Masahiro WATABE, Tokyo (JP)

(73) Assignee: Japan Display Inc., Tokyo (JP)

(21) Appl. No.: 18/651,909

(22) Filed: May 1, 2024

(30) Foreign Application Priority Data
May 12, 2023 (JP) 2023-079338

(51) Int. Cl. H01L 29/786; H01L 29/417

(52) U.S. Cl. CPC H01L 29/7869; H01L 29/41733; H01L 29/78696

(57) ABSTRACT

A semiconductor device according to an embodiment of the present invention includes: a gate electrode; a gate insulating layer; a metal oxide layer containing aluminum as a main component above the gate insulating layer; an oxide semiconductor layer having a polycrystalline structure above the metal oxide layer; a source electrode and a drain electrode contacting the oxide semiconductor layer from above the oxide semiconductor layer; and an insulating layer above the source electrode and the drain electrode, wherein a linear mobility of the semiconductor device is larger than 20 cm²/Vs when (Vg−Vth)×Cox=5×10⁻⁷ C/cm², in the case where the Vg is a voltage supplied to the gate electrode, the Vth is a threshold voltage of the semiconductor device, and the Cox is an electrostatic capacitance of the gate insulating layer sandwiched by the gate electrode and the oxide semiconductor layer.

### CROSS REFERENCE TO RELATED APPLICATIONS

This application claims the benefit of priority to Japanese Patent Application No. 2023-079338, filed on May 12, 2023, the entire contents of which are incorporated herein by reference.

### FIELD

An embodiment of the present invention relates to a semiconductor device. In particular, an embodiment of the present invention relates to a semiconductor device in which an oxide semiconductor is used as a channel.

### BACKGROUND

In recent years, a semiconductor device in which an oxide semiconductor is used as a channel instead of amorphous silicon, low-temperature polysilicon, and single-crystal silicon has been developed (for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device in which an oxide semiconductor is used as a channel can be formed in a simple structure and low-temperature process, similar to the semiconductor device in which amorphous silicon is used as a channel. The semiconductor device in which an oxide semiconductor is used as a channel is known to have higher mobility than the semiconductor device in which amorphous silicon is used as a channel.

It is essential to reduce oxygen defects formed in the oxide semiconductor layer by supplying oxygen to the oxide semiconductor layer in the manufacturing process of the semiconductor device in order for the semiconductor device in which an oxide semiconductor is used as a channel to operate stably. For example, a technique in which an insulating layer covering an oxide semiconductor layer is formed under a condition that the insulating layer contains more oxygen is disclosed as one of the methods of supplying oxygen to an oxide semiconductor layer.

### SUMMARY

A semiconductor device according to an embodiment of the present invention includes: a gate electrode; a gate insulating layer above the gate electrode; a metal oxide layer containing aluminum as a main component above the gate insulating layer; an oxide semiconductor layer having a polycrystalline structure above the metal oxide layer; a source electrode and a drain electrode contacting the oxide semiconductor layer from above the oxide semiconductor layer; and an insulating layer above the source electrode and the drain electrode, wherein a linear mobility of the semiconductor device is larger than 20 cm²/Vs when (Vg−Vth)×Cox=5×10⁻⁷ C/cm², in the case where the Vg is a voltage supplied to the gate electrode, the Vth is a threshold voltage of the semiconductor device, and the Cox is an electrostatic capacitance of the gate insulating layer sandwiched by the gate electrode and the oxide semiconductor layer.

A semiconductor device according to an embodiment of the present invention includes: a gate electrode; a gate insulating layer above the gate electrode; a metal oxide layer containing aluminum as a main component above the gate insulating layer; an oxide semiconductor layer having a polycrystalline structure above the metal oxide layer; a source electrode and a drain electrode contacting the oxide semiconductor layer from above the oxide semiconductor layer; and an insulating layer above the source electrode and the drain electrode, wherein a linear mobility of the semiconductor device is larger than 30 cm²/Vs when (Vg−Vth)×Cox=1×10⁻⁶ C/cm², in the case where the Vg is a voltage supplied to the gate electrode, the Vth is a threshold voltage of the semiconductor device, and the Cox is an electrostatic capacitance of the gate insulating layer sandwiched between the gate electrode and the oxide semiconductor layer.

A semiconductor device according to an embodiment of the present invention includes: a gate electrode; a gate insulating layer above the gate electrode; a metal oxide layer containing aluminum as a main component above the gate insulating layer; an oxide semiconductor layer having a polycrystalline structure above the metal oxide layer; a source electrode and a drain electrode contacting the oxide semiconductor layer from above the oxide semiconductor layer; and an insulating layer above the source electrode and the drain electrode, wherein a normalized linear mobility normalized by a linear mobility of the semiconductor device in a condition of Vg=Vth is larger than 3.0 when (Vg−Vth)×Cox=5×10⁻⁷ C/cm², in the case where the Vg is a voltage supplied to the gate electrode, the Vth is a threshold voltage of the semiconductor device, and the Cox is an electrostatic capacitance of the gate insulating layer sandwiched between the gate electrode and the oxide semiconductor layer.

### BRIEF DESCRIPTION OF DRAWINGS

FIG. 1 is a cross-sectional view showing an outline of a semiconductor device according to an embodiment of the present invention.

FIG. 2 is a plan view showing an outline of a semiconductor device according to an embodiment of the present invention.

FIG. 3 is a flowchart showing a method for manufacturing a semiconductor device according to an embodiment of the present invention.

FIG. 4 is a cross-sectional view showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a plan view showing an outline of a display device according to an embodiment of the present invention.

FIG. 12 is a block diagram showing a circuit configuration of a display device according to an embodiment of the present invention.

FIG. 13 is a circuit diagram showing a pixel circuit of a display device according to an embodiment of the present invention.

FIG. 14 is a cross-sectional view showing an outline of a display device according to an embodiment of the present invention.

FIG. 15 is a plan view of a pixel electrode and a common electrode of a display device according to an embodiment of the present invention.

FIG. 16 is a circuit diagram showing a pixel circuit of a display device according to an embodiment of the present invention.

FIG. 17 is a cross-sectional view showing an outline of a display device according to an embodiment of the present invention.

FIG. 18 is a diagram showing the electrical characteristics of a semiconductor device according to an embodiment of the present invention.

FIG. 19 is a diagram showing the linear mobility of a semiconductor device according to an embodiment of the present invention.

FIG. 20 is a diagram showing a dependency of gate capacitance of the electrical characteristics of a semiconductor device according to an embodiment of the present invention.

FIG. 21 is a diagram showing the dependency of gate capacitance in the electrical characteristics of a semiconductor device according to an embodiment of the present invention.

FIG. 22 is a diagram showing the dependency of gate capacitance in linear mobility of a semiconductor device according to an embodiment of the present invention.

FIG. 23 is a diagram in which the horizontal axis of FIG. 20 is normalized by a threshold voltage and a gate capacitance.

FIG. 24 is a diagram in which the horizontal axis of FIG. 21 is normalized by a threshold voltage and a gate capacitance.

FIG. 25 is a diagram in which the horizontal axis of FIG. 22 is normalized by a threshold voltage and a gate capacitance.

FIG. 26 is a diagram showing the dependency of gate capacitance in normalized linear mobility of a semiconductor device according to an embodiment of the present invention.

### DESCRIPTION OF EMBODIMENTS

Embodiments of the present invention will be described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

In the embodiments of the present invention, a direction from a substrate to an oxide semiconductor layer is referred to as “on” or “above”. Reversely, a direction from the oxide semiconductor layer to the substrate is referred to as “under” or “below”. As described above, for convenience of explanation, although the phrase “above (on)” or “below (under)” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Above or below means a stacking order in a structure in which multiple layers are stacked, and in the case where it is expressed as a pixel electrode above a transistor, it may be a positional relationship where the transistor and the pixel electrode do not overlap each other in a plan view. On the other hand, in the case where it is expressed as a pixel electrode vertically above a transistor, it means a positional relationship where the transistor and the pixel electrode overlap each other in a plan view.

In this specification, the terms “film” and “layer” can optionally be interchanged with each other.

“Display device” refers to a structure configured to display an image using electro-optic layers. For example, the term display device may refer to a display panel including the electro-optic layer, or it may refer to a structure in which other optical members (for example, polarizing member, backlight, touch panel, or the like) are attached to a display cell. The “electro-optic layer” can include a liquid crystal layer, an electroluminescence (EL) layer, an electrochromic (EC) layer, and an electrophoretic layer, as long as there is no technical contradiction. Therefore, although the embodiments described later will be described by exemplifying a liquid crystal display device including a liquid crystal layer and an organic EL display device including an organic EL layer as the display device, the structure in the present embodiment can be applied to a display device including the other electro-optic layers described above.

The expressions “a includes A, B, or C”, “a includes any of A, B, or C”, and “a includes one selected from a group consisting of A, B, and C” do not exclude the case where a includes multiple combinations of A to C unless otherwise specified. Furthermore, these expressions do not exclude the case where a includes other elements.

In addition, the following embodiments may be combined with each other as long as there is no technical contradiction.

An insulating layer formed under a condition containing more oxygen contains many defects. As a result, abnormal characteristics in the semiconductor device or characteristic fluctuations in the reliability test occur. It is considered that the abnormal characteristics and the characteristic fluctuations are caused by an electron becoming trapped in a defect formed in the insulating layer. On the other hand, in the case where an insulating layer containing less defects is used as the insulating layer, the insulating layer cannot contain much oxygen. Therefore, oxygen cannot be sufficiently supplied from the insulating layer to the oxide semiconductor layer. In view of the above, there is a need to realize a structure capable of repairing oxygen defects formed in the oxide semiconductor layer while reducing defects in the insulating layer causing characteristic fluctuations of the semiconductor device.

An object of an embodiment of the present invention is to realize a semiconductor device with high mobility.

### 1. First Embodiment

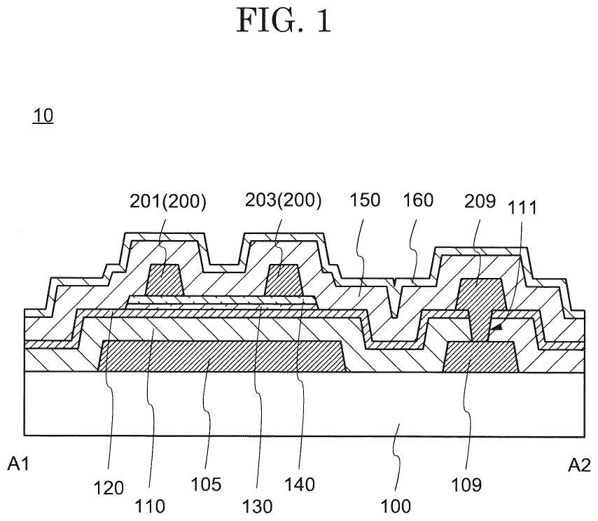

A semiconductor device 10 according to an embodiment of the present invention will be described with reference to FIG. 1 to FIG. 10.

### 1-1. Configuration of Semiconductor Device 10

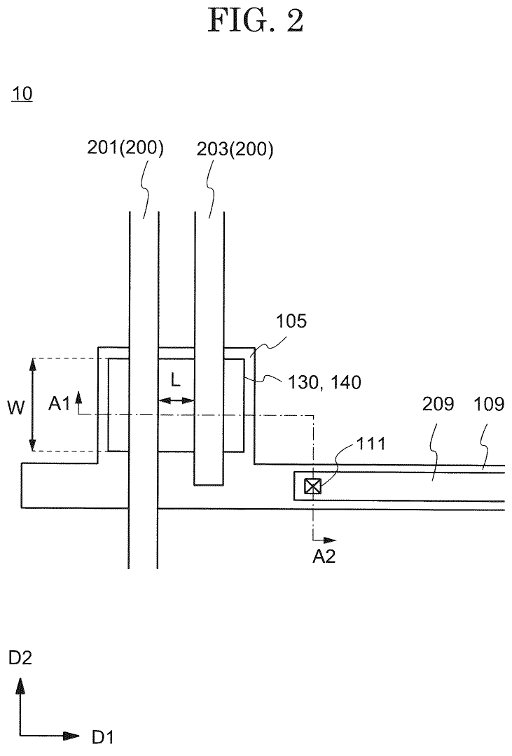

A configuration of the semiconductor device 10 according to an embodiment of the present invention will be described with reference to FIG. 1 and FIG. 2. FIG. 1 is a cross-sectional view schematically showing the semiconductor device 10 according to an embodiment of the present invention. FIG. 2 is a plan view schematically showing the semiconductor device 10 according to an embodiment of the present invention. The cross-sectional view shown in FIG. 1 corresponds to a cross section taken along a line A1-A2 shown in FIG. 2.

The semiconductor device 10 is arranged above a substrate 100 as shown in FIG. 1. The semiconductor device 10 includes a gate electrode 105, gate insulating layers 110 and 120, a metal oxide layer 130, an oxide semiconductor layer 140, a source electrode 201, a drain electrode 203, and insulating layers 150 and 160. In the case where the source electrode 201 and the drain electrode 203 are not particularly distinguished from each other, they may be collectively referred to as a source-drain electrode 200. A bottom-gate transistor in which the gate electrode 105 is arranged below the oxide semiconductor layer 140 will be described in the present embodiment as the semiconductor device 10.

Although the bottom-gate transistor will be exemplified as the semiconductor device 10 in the present embodiment, the semiconductor device 10 is not limited to the bottom-gate transistor. For example, the semiconductor device 10 may be a dual-gate transistor in which the gate electrode is arranged both above and below the oxide semiconductor layer 140.

The gate electrode 105 is arranged on the substrate 100. The gate insulating layers 110 and 120 are arranged on the substrate 100 and the gate electrode 105. The gate insulating layers 110 and 120 have a stacked structure. The metal oxide layer 130 is arranged on the gate insulating layer 120. The oxide semiconductor layer 140 is arranged on the metal oxide layer 130. The source electrode 201 and the drain electrode 203 are arranged on the oxide semiconductor layer 140. The source electrode 201 and the drain electrode 203 are in contact with the oxide semiconductor layer 140 from above. The insulating layers 150 and 160 are arranged on the oxide semiconductor layer 140, the source electrode 201, and the drain electrode 203. The insulating layers 150 and 160 have a stacked structure. The insulating layer 160 is arranged on the insulating layer 150. That is, the insulating layers 150 and 160 cover the source electrode 201 and the drain electrode 203. The insulating layer 150 is in contact with the oxide semiconductor layer 140.

The oxide semiconductor layer 140 has light transmittance and has a polycrystalline structure including a plurality of crystal grains. Although details will be described later, the oxide semiconductor layer 140 having a polycrystalline structure can be formed by using a Poly-OS (Poly-crystalline Oxide Semiconductor) technique. Hereinafter, although a configuration of the oxide semiconductor layer 140 will be described, an oxide semiconductor having a polycrystalline structure may be referred to as a Poly-OS.

For example, the particle diameter of the crystal grain contained in the Poly-OS is 0.1 μm or more, 0.3 μm or more, or 0.5 μm or more. For example, the particle diameter of the crystal grain can be obtained using a cross-sectional SEM observation, a cross-sectional TEM observation, or an electron-beam backscattering diffractometry (Electron Back Scattered Diffraction: EBSD) method.

As described above, since the particle diameter of the crystal grain contained in the Poly-OS is 0.1 μm or more, in the oxide semiconductor layer 140 having a thickness of 10 nm or more and 30 nm or less, there is a region containing only one crystal grain along a thickness direction, in a cross-sectional view.

For example, a thickness of the gate insulating layer 110 is 50 nm or more and 500 nm or less, 50 nm or more and 400 nm or less, 50 nm or more and 300 nm or less, 50 nm or more and 150 nm or less, or 50 nm or more and 100 nm or less. For example, a thickness of the gate insulating layer 120 is 10 nm or more and 200 nm or less or 10 nm or more and 100 nm or less. For example, the total thickness of the gate insulating layers 110 and 120 is 100 nm or more and 700 nm or less, 100 nm or more and 500 nm or less, 100 nm or more and 400 nm or less, 100 nm or more and 250 nm or less, 100 nm or more and 200 nm or less, or 100 nm or more and 150 nm or less.

For example, a thickness of the metal oxide layer 130 is 1 nm or more and 10 nm or less or 1 nm or more and 5 nm or less. Aluminum oxide is used as the metal oxide layer 130 in the present embodiment. Aluminum oxide has a high barrier property against a gas such as oxygen or hydrogen. The barrier property means a function of suppressing the permeation of the gas such as oxygen or hydrogen through the aluminum oxide. That is, even if the gas such as oxygen or hydrogen is released from the layer arranged below an aluminum oxide film, the gas does not move to the layer arranged above the aluminum oxide film. Alternatively, even if the gas such as oxygen or hydrogen is released from the layer arranged above the aluminum oxide film, the gas does not move to the layer arranged below the aluminum oxide film.

A thickness of the oxide semiconductor layer 140 is 10 nm or more and 50 nm or less, 10 nm or more and 40 nm or less, or 10 nm or more and 30 nm or less. A thickness of the insulating layer 150 is 50 nm or more and 300 nm or less, 60 nm or more and 200 nm or less, or 70 nm or more and 150 nm or less.

A wiring 109 is formed in the same layer as the gate electrode 105. That is, the wiring 109 is in contact with the substrate 100 and the gate insulating layer 110 in the same manner as the gate electrode 105. A wiring 209 is formed in the same layer as the source electrode 201 and the drain electrode 203. That is, the wiring 209 is in contact with the insulating layer 150 in the same manner as the source electrode 201 and the drain electrode 203. A contact hole 111 is arranged in the gate insulating layers 110 and 120 in a region overlapping the wiring 109. The wiring 209 is connected to the wiring 109 via the contact hole 111. The wiring 109 and the wiring 209 function as gate wirings.

The oxide semiconductor layer 140 overlaps the gate electrode 105 in a plan view as shown in FIG. 2. A direction D1 is a direction connecting the source electrode 201 and the drain electrode 203. A direction D2 is a direction perpendicular to the direction D1. A channel region in the semiconductor device 10 is a region where the gate electrode 105 overlaps the oxide semiconductor layer 140 and is sandwiched between the source electrode 201 and the drain electrode 203. A channel length L is a length of the channel region in the direction D1, and corresponds to a length between the source electrode 201 and the drain electrode 203 in the direction D1. A channel width W is a width of the channel region in the direction D2 and corresponds to a width of the oxide semiconductor layer 140 in the direction D2. In a plan view, a region where the oxide semiconductor layer 140 overlaps the source electrode 201 is a source region, and a region where the oxide semiconductor layer 140 overlaps the drain electrode 203 is a drain region. That is, the channel region is positioned between the source region and the drain region.

In a plan view, a planar pattern of the metal oxide layer 130 is substantially the same as a planar pattern of the oxide semiconductor layer 140. In other words, end portions of the metal oxide layer 130 and end portions of the oxide semiconductor layer 140 substantially coincide with each other. Referring to FIG. 1 and FIG. 2, the lower surface of the oxide semiconductor layer 140 is covered with the metal oxide layer 130. In particular, the entire lower surface of the oxide semiconductor layer 140 is covered with the metal oxide layer 130 in the semiconductor device 10 according to the present embodiment.

The wirings 109 and 209 extend in the direction D1. A width of the wiring 109 is larger than a width of the wiring 209 in the direction D2. The contact hole 111 is arranged at an end portion of the wiring 209 in a direction opposite to the direction D1. Although a configuration in which the wiring 109 extends in the direction D1 with the wiring 209 is exemplified in FIG. 2, the configuration is not limited to this configuration. The wiring 209 may extend in the direction D1 beyond the end portion of the wiring 109 in the direction D1. The width of the wiring 109 in the direction D2 may be the same as the width of the wiring 209 and may be smaller than the wiring 209.

### 1-2. Electrical Characteristics of Semiconductor Device 10

A gate capacitance Cox is an electrostatic capacitance of a dielectric (the gate insulating layers 110 and 120 and the metal oxide layer 130) arranged between the oxide semiconductor layer 140 and the gate electrode 105 in a carrier-generated state when a voltage for controlling the semiconductor device 10 to the on-state is supplied to the gate electrode 105. Specifically, the gate capacitance Cox is calculated based on the thicknesses and dielectric constants of the gate insulating layers 110 and 120 and the metal oxide layer 130 in the channel region.

The semiconductor device 10 according to the present embodiment has the above-described configuration, so that it is possible to obtain higher linear mobility than a semiconductor device (conventional oxide semiconductor) using a conventional oxide semiconductor (for example, having a composition ratio of In:Ga:Zn:O=1:1:1:4 and having an amorphous structure). The linear mobility means the mobility in a linear region in the electrical characteristics (Id-Vg characteristics) of the transistor. The linear mobility in the present embodiment is a mobility calculated from the Id-Vg characteristics of the semiconductor device 10 when a voltage between the source electrode 201 and the drain electrode 203 is 0.1 V. A voltage supplied to the drain electrode 203 when 0 V is supplied to the source electrode 201 is referred to as a drain voltage Vd.

In the semiconductor device 10, the defects in the film of the oxide semiconductor layer 140 that function as channels are less than those in the film of the conventional oxide semiconductor. As a result, the mobility calculated from the electric characteristics of the semiconductor device 10 according to the present embodiment is higher than the mobility calculated from the electric characteristics of the conventional semiconductor device. In particular, in the conventional semiconductor device, a high mobility cannot be obtained when the drain voltage Vd and the gate voltage Vg are low, whereas in the semiconductor device 10 according to the present embodiment, a high mobility can be obtained even when the drain voltage Vd and the gate voltage Vg are low. The gated voltage Vg is the voltage supplied to the gate electrode 105.

In the case where the mobility is calculated based on the electrical characteristics (Id-Vg characteristics) of the semiconductor device, differences in the amount of defects formed in the oxide semiconductor layer and the gate capacitance Cox affect the mobility. Therefore, it is difficult to evaluate differences in the mobility due to physical properties and structures of the oxide semiconductor layer.

For example, if defects are formed in the oxide semiconductor layer of the semiconductor device, the quantity of defects affects a threshold voltage Vth in the Id-Vg characteristics of the semiconductor device. Specifically, when a voltage is supplied to the gate electrode of the semiconductor device, charges excited in the channel fill the defects when the gate voltage Vg is small. Therefore, since the charges do not contribute to a drain current Id, the rising voltage of the Id-Vg characteristics is shifted to a higher voltage than the original rising voltage.

The threshold voltage Vth is a gate voltage Vg when a current of “channel width W/channel length L×10 nA” flows through the semiconductor device in the Id-Vg characteristics when the drain voltage Vd is 0.1 V.

Further, the gate capacitance Cox depends on the thickness of the gate insulating layer, the dielectric constant of the material used as the gate insulating layer, and the like. Therefore, even when the same gate voltage Vg is supplied, the larger the gate capacitance Cox, the higher the carrier concentration generated in the channel. Therefore, when the mobility is compared at the same gate voltage, the larger the gate capacitance Cox, the more carriers are generated to the channel. Therefore, the larger the gate capacitance Cox, the higher the mobility. That is, since the amount of charges accumulated in the channel vary depending on the thickness of the gate insulating layer, there is a possibility that the mobility cannot be correctly evaluated.

As described above, in order to reduce the influence of the defects formed in the oxide semiconductor layer and the influence on the mobility due to the gate capacitance Cox, in the present embodiment, the measured Id-Vg characteristics are normalized by the threshold voltage Vth and the gate capacitance Cox. Specifically, in the Id-Vg characteristics, the normalization is performed by converting the horizontal axis from “gate voltage Vg” to “(gate voltage Vg-threshold voltage Vth)×gate capacitance Cox”. The gate voltage Vg×gate capacitance Cox corresponds to the amount of charges excited in the channel.

Although details will be described later, the linear mobility of the semiconductor device 10 in the Id-Vg characteristics normalized as described above is larger than 20 cm²/Vs when (Vg−Vth)×Cox=5×10⁻⁷ C/cm². Furthermore, the linear mobility of the semiconductor device 10 is larger than 30 cm²/Vs when (Vg−Vth)× Cox=1×10⁻⁶ C/cm²).

In addition, the normalized linear mobility of the semiconductor device 10, where the linear mobility with (Vg−Vth)×Cox as the horizontal axis is normalized by the linear mobility in Vg=Vth, is larger than 3.0 for (Vg−Vth)×Cox=5×10⁻⁷ C/cm². Furthermore, the normalized linear mobility of the semiconductor device 10 is larger than 4.0 for (Vg−Vth)× Cox=1×10⁻⁶ C/cm².

### 1-3. Material of Each Component in Semiconductor Device 10

A rigid substrate having translucency, such as a glass substrate, a quartz substrate, a sapphire substrate, or the like, is used as the substrate 100. In the case where the substrate 100 needs to have flexibility, a substrate containing a resin such as a polyimide substrate, an acryl substrate, a siloxane substrate, or a fluororesin substrate is used as the substrate 100. In the case where the substrate containing a resin is used as the substrate 100, impurities may be introduced into the resin in order to improve the heat resistance of the substrate 100. In particular, in the case where the semiconductor device 10 is a top-emission display, since the substrate 100 does not need to be transparent, impurities that deteriorate the translucency of the substrate 100 may be used. In the case where the semiconductor device 10 is used for an integrated circuit that is not a display device, a substrate without translucency such as a semiconductor substrate such as a silicon substrate, a silicon carbide substrate, a compound semiconductor substrate, or a conductive substrate such as a stainless substrate is used as the substrate 100.

Common metal materials are used as the gate electrode 105, the source-drain electrode 200, and the wirings 109 and 209. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof are used as these members. The above-described materials may be used in a single layer or stacked layer as the gate electrode 105, the source-drain electrode 200, and the wirings 109 and 209.

Common insulating materials are used as the gate insulating layers 110 and 120 and the insulating layers 150 and 160. For example, an inorganic insulating layer containing oxygen such as silicon oxide (SiOₓ), silicon oxynitride (SiOₓN_{y}), aluminum oxide (AlOₓ), and aluminum oxynitride (AlOₓN_{y}) is used as the gate insulating layer 120 and the insulating layer 150. An inorganic insulating layer containing nitrogen such as silicon nitride (SiNₓ), silicon nitride oxide (SiNₓO_{y}), aluminum nitride (AlNₓ), and aluminum nitride oxide (AlNₓO_{y}) is used as the gate insulating layer 110 and the insulating layer 160. However, an inorganic insulating layer containing oxygen as described above may be used as the gate insulating layer 110 and the insulating layer 160. An inorganic insulating layer containing nitrogen as described above may be used as the gate insulating layer 120 and the insulating layer 150.

An insulating layer having a function of releasing oxygen by a heat treatment is used as the insulating layer 150. That is, an oxide insulating layer containing an excessive amount of oxygen is used as the insulating layer 150. For example, the temperature of the heat treatment in which the insulating layer 150 releases oxygen is 600° C. or lower, 500° C. or lower, 450° C. or lower, or 400° C. or lower. That is, for example, the insulating layer 150 releases oxygen at a heat treatment temperature performed in a manufacturing process of the semiconductor device 10 when a glass substrate is used as the substrate 100.

An insulating layer with few defects is used as the gate insulating layer 120. For example, in the case where the composition ratio of oxygen in the gate insulating layer 120 is compared with the composition ratio of oxygen in an insulating layer having a composition similar to that of the gate insulating layer 120 (hereinafter referred to as “other insulating layer”), the composition ratio of oxygen in the gate insulating layer 120 is closer to the stoichiometric ratio with respect to the insulating layer than the composition ratio of oxygen in the other insulating layer. Specifically, in the case where silicon oxide (SiOₓ) is used for each of the gate insulating layer 120 and the insulating layer 150, the composition ratio of oxygen in the silicon oxide used as the gate insulating layer 120 is closer to the stoichiometric ratio of silicon oxide than the composition ratio of oxygen in the silicon oxide used as the insulating layer 150. For example, a layer in which no defects are observed when evaluated by an electron-spin resonance (ESR) method may be used as the gate insulating layer 120.

SiOₓN_{y} and AlOₓN_{y} are a silicon compound and aluminum compound containing a smaller proportion (x>y) of nitrogen (N) than oxygen (O). SiNₓO_{y} and AlNₓO_{y} are a silicon compound and aluminum compound containing a smaller proportion (x>y) of oxygen than nitrogen.

A metal oxide containing aluminum as a main component is used as the metal oxide layer 130. For example, an inorganic insulating layer such as aluminum oxide (AlOₓ) or aluminum oxynitride (AlOₓN_{y}) is used as the metal oxide layer 130. The “metal oxide layer 130 containing aluminum as a main component” means that the proportion of aluminum contained in the metal oxide layer 130 is 1% or more of the entire metal oxide layer. The proportion of aluminum contained in the metal oxide layer 130 may be 5% or more and 70% or less, 10% or more and 60% or less, or 30% or more and 50% or less of the entire metal oxide layer. The proportion may be a mass ratio or a weight ratio.

A metal oxide having semiconductor properties can be used as the oxide semiconductor layer 140. The oxide semiconductor layer 140 has a polycrystalline structure. The oxide semiconductor layer 140 having a polycrystalline structure can be fabricated using a Poly-OS technique.

A metal oxide having semiconductor properties may be used as the oxide semiconductor layer 140. For example, an oxide semiconductor containing indium (In), gallium (Ga), zinc (Zn), and oxygen (O) may be used as the oxide semiconductor layer 140. For example, an oxide semiconductor having a composition ratio of In:Ga:Zn:O=1:1:1:4 may be used as the oxide semiconductor layer 140. However, the oxide semiconductor containing In, Ga, Zn and O used in the present embodiment is not limited to the above-described composition. An oxide semiconductor having a composition other than the above may be used as the oxide semiconductor. For example, an oxide semiconductor layer having a higher ratio of In than those described above may be used to improve mobility. On the other hand, in order to increase the bandgap and reduce the effect of photoirradiation, an oxide semiconductor layer having a larger ratio of Ga than those described above may be used.

For example, an oxide semiconductor containing two or more metals including indium (In) may be used as the oxide semiconductor layer 140 in which the ratio of In is larger than that described above. In this case, the ratio of indium with respect to the entire oxide semiconductor layer 140 may be 50% or more. Gallium (Ga), zinc (Zn), aluminum (Al), hafnium (Hf), yttrium (Y), zirconia (Zr), and lanthanoids may be used as the oxide semiconductor layer 140 in addition to indium. Elements other than those described above may be used as the oxide semiconductor layer 140.

Other elements may be added to the oxide semiconductor containing In, Ga, Zn, and O as the oxide semiconductor layer 140, and metal elements such as Al, Sn may be added. In addition to the above oxide semiconductor, an oxide semiconductor (IGO) containing In, Ga, an oxide semiconductor (IZO) containing In, Zn, an oxide semiconductor (ITZO) containing In, Sn, Zn, or an oxide semiconductor containing In, W may be used as the oxide semiconductor layer 140.

In the case where the ratio of the indium element is large, the oxide semiconductor layer 140 is likely to crystallize. As described above, in the oxide semiconductor layer 140, the oxide semiconductor layer 140 having a polycrystalline structure can be obtained by using a material in which the ratio of the indium element with respect to the total metal element is 50% or more. The oxide semiconductor layer 140 preferably contains gallium as a metal element other than indium. Gallium belongs to the same Group 13 element as indium. Therefore, the crystallinity of the oxide semiconductor layer 140 is not inhibited by gallium, and the oxide semiconductor layer 140 has a polycrystalline structure.

Although a detailed method of manufacturing the oxide semiconductor layer 140 will be described later, the oxide semiconductor layer 140 can be formed using a sputtering method. A composition of the oxide semiconductor layer 140 formed by the sputtering method depends on a composition of a sputtering target. Even though the oxide semiconductor layer 140 has a polycrystalline structure, the composition of the sputtering target is substantially consistent with the composition of the oxide semiconductor layer 140. In this case, the composition of the metal element of the oxide semiconductor layer 140 can be specified based on the composition of the metal element of the sputtering target.

In the case where the oxide semiconductor layer 140 has a polycrystalline structure, a composition of the oxide semiconductor layer may be specified using X-ray diffraction (X-ray Diffraction: XRD). Specifically, a composition of the metal element of the oxide semiconductor layer can be specified based on the crystalline structure and the lattice constant of the oxide semiconductor layer obtained by the XRD method. Furthermore, the composition of the metal element of the oxide semiconductor layer 140 can also be identified using fluorescent X-ray analysis, Electron Probe Micro Analyzer (EPMA) analysis, or the like. However, the oxygen element contained in the oxide semiconductor layer 140 may not be specified by these methods because the oxygen element varies depending on the sputtering process conditions.

### 1-4. Method for Manufacturing Semiconductor Device 10

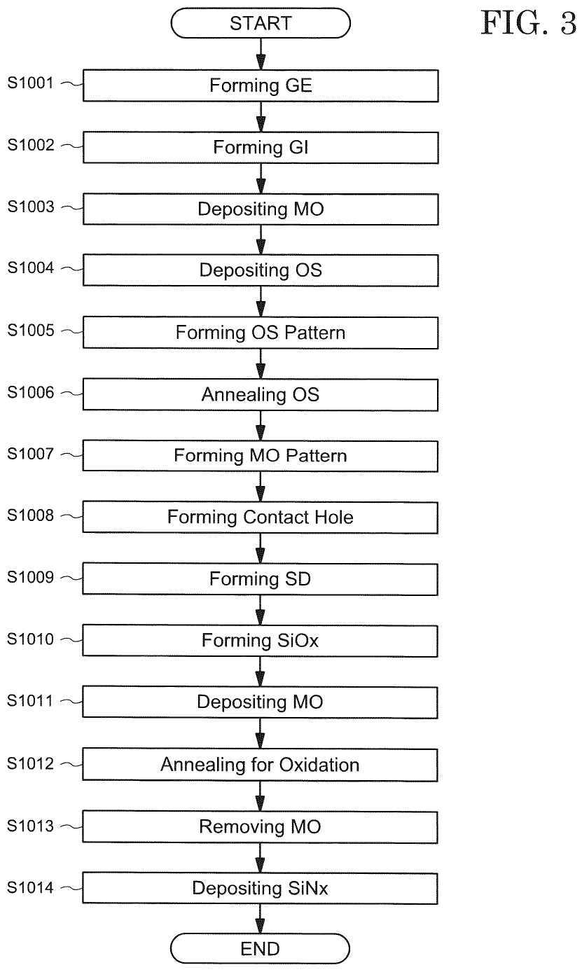

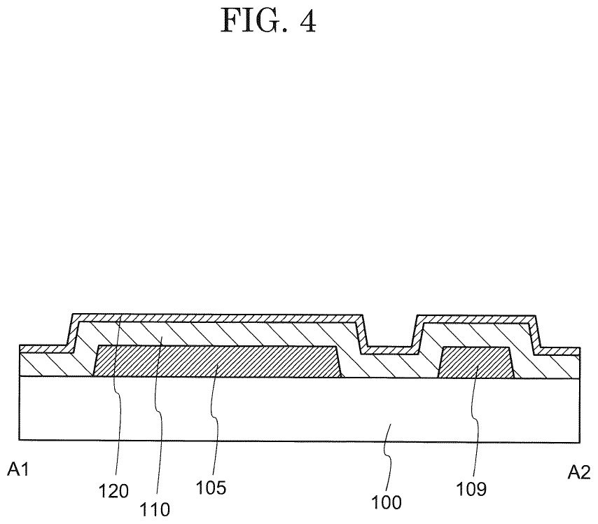

A method for manufacturing the semiconductor device 10 according to an embodiment of the present invention will be described with reference to FIG. 3 to FIG. 10. FIG. 3 is a flowchart illustrating a method for manufacturing the semiconductor device 10 according to an embodiment of the present invention. FIG. 4 to FIG. 10 are schematic cross-sectional views showing a method for manufacturing the semiconductor device 10 according to an embodiment of the present invention. Hereinafter, each step of the flowchart shown in FIG. 3 will be described in order.

In step S1001 (“Forming GE”) of FIG. 3, the gate electrode 105 is formed on the substrate 100 (see FIG. 4). The wiring 109 is formed with the gate electrode 105 in the same step. The gate electrode 105 and the wiring 109 are formed by a PVD (Physical Vapor Deposition) method such as a sputtering method or a vacuum-deposition method.

In step S1002 (“Forming GI”) of FIG. 3, the gate insulating layers 110 and 120 are formed on the gate electrode 105 and the wiring 109 (see FIG. 4). The gate insulating layers 110 and 120 are formed by a CVD (Chemical Vapor Deposition) method or a sputtering method. For example, an insulating material containing nitrogen is used as the gate insulating layer 110. With this configuration, it is possible to block impurities diffusing from the substrate 100 toward the oxide semiconductor layer 140. An insulating material containing oxygen is used as the gate insulating layer 120.

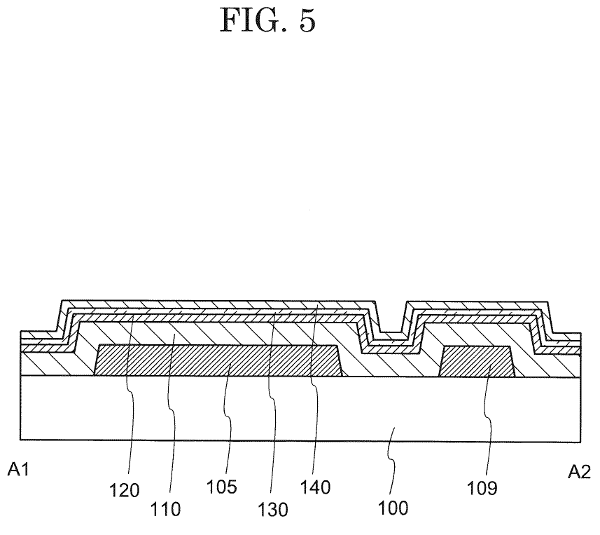

An oxide insulating layer with few defects is used as the gate insulating layer 120. In order to form the oxide insulating layer with few defects as the insulating layer 120, the insulating layer 120 can be deposited at a deposition temperature of 350° C. or higher. In step S1003 (“Depositing MO”) of FIG. 3, the metal oxide layer 130 is formed on the gate insulating layers 110 and 120 (see FIG. 5). The metal oxide layer 130 is deposited by a sputtering method or an atomic layer deposition method (ALD).

A metal oxide containing aluminum as a main component is used as the metal oxide layer 130. For example, an inorganic insulating layer such as aluminum oxide (AlOₓ) or aluminum oxynitride (AlOₓN_{y}) is used as the metal oxide layer 130.

In step S1004 (“Depositing OS”) of FIG. 3, the oxide semiconductor layer 140 is formed on the metal oxide layer 130 (see FIG. 5). The oxide semiconductor layer 140 is deposited by the sputtering method or the atomic layer deposition method (ALD).

In the case where the oxide semiconductor layer 140 is crystallized by OS annealing described later, the oxide semiconductor layer 140 after the deposition and before OS annealing is preferably amorphous (a state where the crystalline component of the oxide semiconductor is small). That is, the conditions for forming the oxide semiconductor layer 140 are preferably such that the oxide semiconductor layer 140 immediately after the deposition is not crystallized as much as possible. For example, in the case where the oxide semiconductor layer 140 is formed by a sputtering method, the oxide semiconductor layer 140 is formed while controlling the temperature of an object to be film-formed (the substrate 100 and the structure formed thereon).

When the deposition is performed on the object to be film-formed by the sputtering method, ions generated in the plasma and atoms recoiled by a sputtering target collide with the object to be film-formed, so that the temperature of the object to be film-formed increases with the deposition process. When the temperature of the object to be film-formed during the deposition process increases, crystalline components are contained in the oxide semiconductor layer 140 immediately after the deposition. When crystal components are contained in the oxide semiconductor layer 140, the particle diameter cannot be increased by subsequent OS annealing. In order to control the temperature of the object to be film-formed as described above, for example, by performing the deposition while cooling the object to be film-formed, the crystalline components contained in the oxide semiconductor layer 140 can be reduced.

For example, the object to be film-formed can be cooled from the surface opposite to the deposition surface so that the temperature of the deposition surface of the object to be film-formed (hereinafter, referred to as “deposition temperature”) is 100° C. or lower, 70° C. or lower, 50° C. or lower, or 30° C. or lower. In particular, the deposition temperature of the oxide semiconductor layer 140 is preferably 50° C. or lower. Forming the oxide semiconductor layer 140 while the substrate 100 is cooled makes it possible to obtain the oxide semiconductor layer 140 with few crystalline components immediately after the deposition. In the present embodiment, the oxide semiconductor layer 140 is formed at a deposition temperature of 50° C. or lower, and the OS annealing, which will be described later, is performed at a heat temperature of 400° C. or higher.

In a sputtering process, the oxide semiconductor layer 140 having an amorphous structure is formed under the condition that the oxygen partial pressure is 10% or less. When the oxygen partial pressure is high, the oxide semiconductor layer 140 immediately after the film formation contains crystalline components due to excessive oxygen contained in the oxide semiconductor layer 140. Therefore, the deposition of the oxide semiconductor layer 140 is preferably performed under the condition where the oxygen partial pressure is low. For example, the oxygen partial pressure is 1% or more and 5% or less, or 2% or more and 4% or less. Under the condition where the oxygen partial pressure is less than 1%, the distribution of oxygen in a deposition apparatus tends to be uneven. As a result, the composition of oxygen in the oxide semiconductor layer is also uneven, and an oxide semiconductor layer containing a large amount of crystal components is formed, or an oxide semiconductor layer that is not crystallized is formed even when the OS annealing process is performed later.

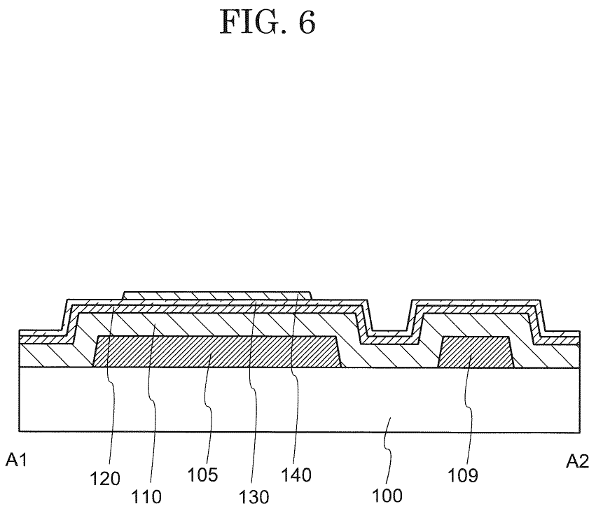

In step S1005 (“Forming OS Pattern”) of FIG. 3, a pattern of the oxide semiconductor layer 140 is formed (see FIG. 6). A resist mask (not shown) is formed on the oxide semiconductor layer 140, and the oxide semiconductor layer 140 is etched using the resist mask to form the pattern. Wet etching may be used, or dry etching may be used for the etching of the oxide semiconductor layer 140. Etching can be performed using an acidic etchant for the wet etching. For example, oxalic acid, PAN, sulfuric acid, hydrogen peroxide solution, or hydrofluoric acid can be used as the etchant. Through these steps, the patterned oxide semiconductor layer 140 can be formed. Thereafter, the resist mask is removed.

Forming the patterned oxide semiconductor layer 140 (for example, patterning of the oxide semiconductor layer 140) is preferably performed before the OS annealing. Since the oxide semiconductor layer 140 after the OS annealing has high etching resistance, processing by etching is difficult.

In step S1006 (“Annealing OS”) of FIG. 3, after the patterned oxide semiconductor layer 140 is formed, the heat treatment (OS annealing) is performed on the oxide semiconductor layer 140. In the OS annealing, the substrate 100 on which the oxide semiconductor layer 140 is formed is held at a predetermined reached temperature for a predetermined period. The predetermined reached temperature is 300° C. or higher and 500° C. or lower, or 350° C. or higher and 450° C. or lower. The holding time at the reached temperature is 15 minutes or more and 120 minutes or less, or 30 minutes or more and 60 minutes or less. By performing OS annealing, the oxide semiconductor layer 140 having an amorphous structure is crystallized, and the oxide semiconductor layer 140 (Poly-OS) having a polycrystalline structure is formed.

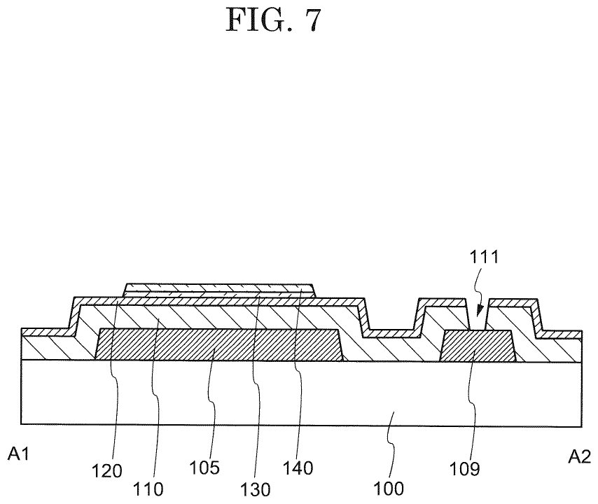

In step S1007 (“Forming MO Pattern”) of FIG. 3, the metal oxide layer 130 formed on the entire surface of the substrate 100 is patterned (see FIG. 7). The oxide semiconductor layer 140 sufficiently crystallized by the heat treatment has high-etching resistance. Therefore, the metal oxide layer 130 can be etched using the crystallized oxide semiconductor layer 140 as a mask. Wet etching may be used, or dry etching may be used for the etching of the metal oxide layer 130. For example, dilute hydrofluoric acid (DHF) is used for the wet etching. By etching the metal oxide layer 130 using the oxide semiconductor layer 140 as a mask, the photolithography step can be omitted. The step of etching the metal oxide layer 130 using the oxide semiconductor layer 140 as a mask may be omitted.

In step S1008 (“Forming Contact Hole”) of FIG. 3, the contact hole 111 is formed in the gate insulating layers 110 and 120 (see FIG. 7). An upper surface of the wiring 109 is exposed by forming the contact hole. In the case where the wiring 209 and the wiring 109 do not need to be connected to each other, the step S1008 may be omitted.

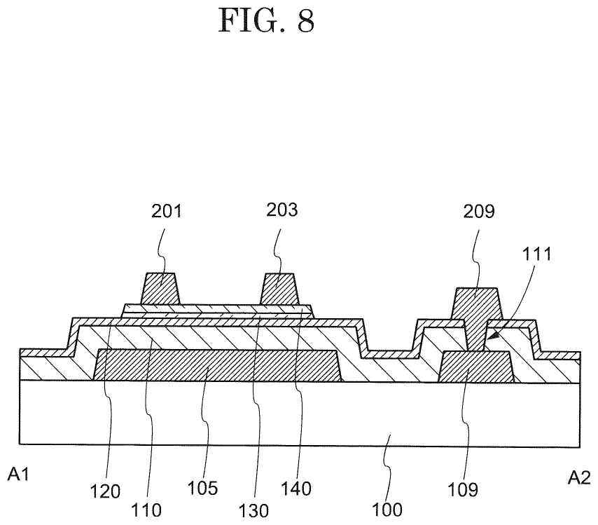

In step S1009 (“Forming SD”) of FIG. 3, the source electrode 201, the drain electrode 203, and the wiring 209 are formed (see FIG. 8). The source electrode 201, the drain electrode 203, and the wiring 209 are formed by a sputtering method, and are formed by a photolithography process and an etching process. The wiring 209 and the wiring 109 are connected via the contact hole 111.

Wet etching may be used, or dry etching may be used for the etching of the source electrode 201, the drain electrode 203, and the wiring 209. An aluminum mixed acid solution or a mixed solution of hydrogen peroxide solution and ammonia solution (H₂O₂/NH₃ solution) can be used for the wet etching. A fluorine-containing gas such as sulfur hexafluoride gas (SF₆) or a chlorine-containing gas such as chlorine gas (Cl₂) can be used for the dry etching.

Poly-OS has an excellent etching resistance. Specifically, the etching rate of Poly-OS with respect to the etchant or the etching gas used to form the source electrode 201 and the drain electrode 203 is very low. This means that Poly-OS is hardly etched by the etchant or the etching gas. Therefore, in the semiconductor device 10, even if a conductive film is deposited directly on the oxide semiconductor layer 140 and the source electrode 201 and the drain electrode 203 are formed by patterning the conductive film, the channel region of the oxide semiconductor layer 140 is hardly etched. As a result, the selection of conductive materials that can be used as the source electrode 201, the drain electrode 203, and the wiring 209 increases. For example, in order to form the source electrode 201 and the drain electrode 203, the oxide semiconductor layer 140 can be suppressed from decreasing in film thickness even when a conductive film using a stacked structure of MoW, Al, MoW or MoW or a single layer structure of MoW alloy is processed by wet etching.

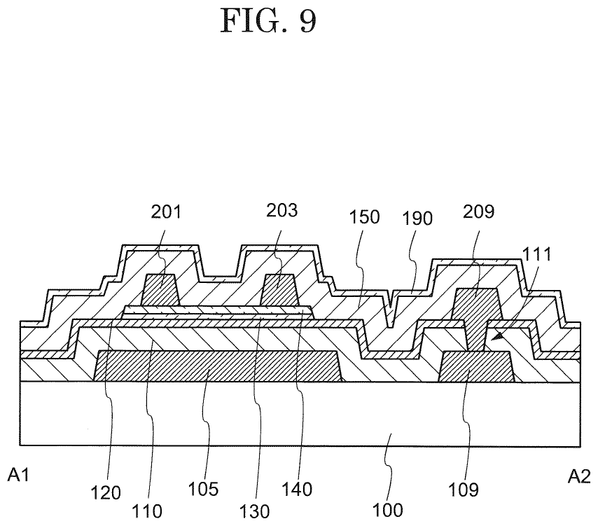

In step S1010 (“Forming SiOₓ”) of FIG. 3, the insulating layer 150 is formed on the oxide semiconductor layer 140, the source electrodes 201, and the drain electrode 203 (see FIG. 9). An insulating material containing oxygen is preferably used as the insulating layer 150. For example, silicon oxide (SiOₓ) or silicon oxynitride (SiOₓN_{y}) is used as the insulating layer 150.

The insulating layer 150 can be deposited using the same deposition method as the gate insulating layers 110 and 120. In order to increase the composition ratio of oxygen in the insulating layer 150, the film may be formed at a relatively low temperature (for example, a deposition temperature of less than 350° C.). Further, after the insulating layer 150 is formed, an oxygen-implanting process may be performed on part of the insulating layer 150.

In step S1011 (“Depositing MO”) of FIG. 3, a metal oxide layer 190 is formed on the insulating layer 150 (see FIG. 9). The metal oxide layer 190 is deposited by the sputtering method or the atomic layer deposition method (ALD).

A metal oxide containing aluminum as a main component is used as the metal oxide layer 190. For example, an inorganic insulating layer such as aluminum oxide (AlOₓ) or aluminum oxynitride (AlOₓN_{y}) is used as the metal oxide layer 190. The metal oxide layer containing aluminum as a main component means that the proportion of aluminum contained in the metal oxide layer is 1% or more of the entire metal oxide layer 190. The proportion of aluminum contained in the metal oxide layer 190 may be 5% or more and 70% or less, 10% or more and 60% or less, or 30% or more and 50% or less of the entire metal oxide layer 190. The proportion may be a mass ratio or a weight ratio.

A thickness of the metal oxide layer 190 is 1 nm or more and 50 nm or less, preferably 1 nm or more and 30 nm or less. Aluminum oxide is preferably used as the metal oxide layer 190. Aluminum oxide has a high barrier property against gas such as oxygen or hydrogen. In this case, the barrier property means the function of suppressing the permeation of the gas such as oxygen or hydrogen into aluminum oxide. That is, the high barrier property of the aluminum oxide to the gas such as oxygen or hydrogen means that the aluminum oxide does not move the gas such as oxygen or hydrogen in the layer arranged below the aluminum oxide film to the layer arranged above the aluminum oxide film. Alternatively, it means that the aluminum oxide does not move the gas such as oxygen or hydrogen in the layer arranged above the aluminum oxide film to the layer arranged below the aluminum oxide film.

In step S1012 (“Annealing for Oxidation”) of FIG. 3, a heat treatment is performed while the insulating layer 150 and the metal oxide layer 190 are formed on the oxide semiconductor layer 140. In this case, for example, the oxidation annealing may be performed at 300° C. or higher and 450° C. or lower. Through this step, the oxygen released from the insulating layer 150 is supplied to the oxide semiconductor layer 140. Since the metal oxide layer 190 is arranged so as to cover the substrate 100, it is possible to suppress the oxygen released from the insulating layer 150 from being released to the outside of the metal oxide layer 190.

Many oxygen defects occur in the oxide semiconductor layer 140 during the process from the deposition of the oxide semiconductor layer 140 to the deposition of the insulating layer 150 on the oxide semiconductor layer 140. However, oxidation annealing of step S1012 supplies oxygen released from the insulating layer 150 to the oxide semiconductor layer 140 and repairs oxygen defects.

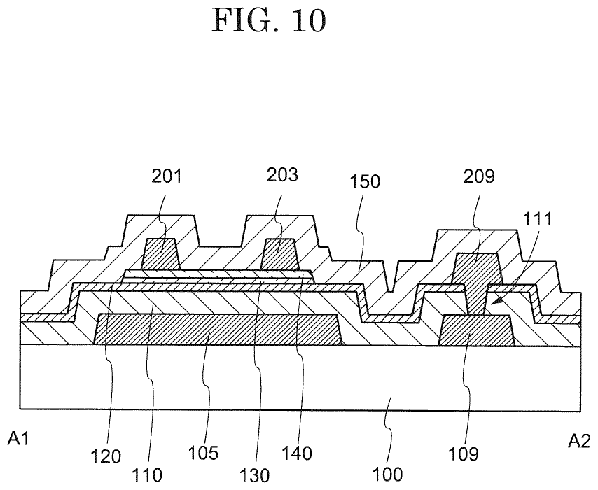

In step S1013 (“Removing MO”) of FIG. 3, the metal oxide layer 190 is removed (see FIG. 10). For example, the metal oxide layer 190 can be removed using dilute hydrofluoric acid (DHF).

In step S1014 (“Depositing SiNₓ”) of FIG. 3, the insulating layer 160 is deposited on the insulating layer 150 (see FIG. 1). An insulating material containing nitrogen is preferably used as the insulating layer 160. For example, silicon nitride (SiNₓ) or silicon nitride oxide (SiNₓO_{y}) is used as the insulating layer 160. The insulating layer 160 can be deposited using the same deposition method as the gate insulating layer 110.

Through the above steps, the semiconductor device 10 shown in FIG. 1 can be manufactured.

### 2. Second Embodiment

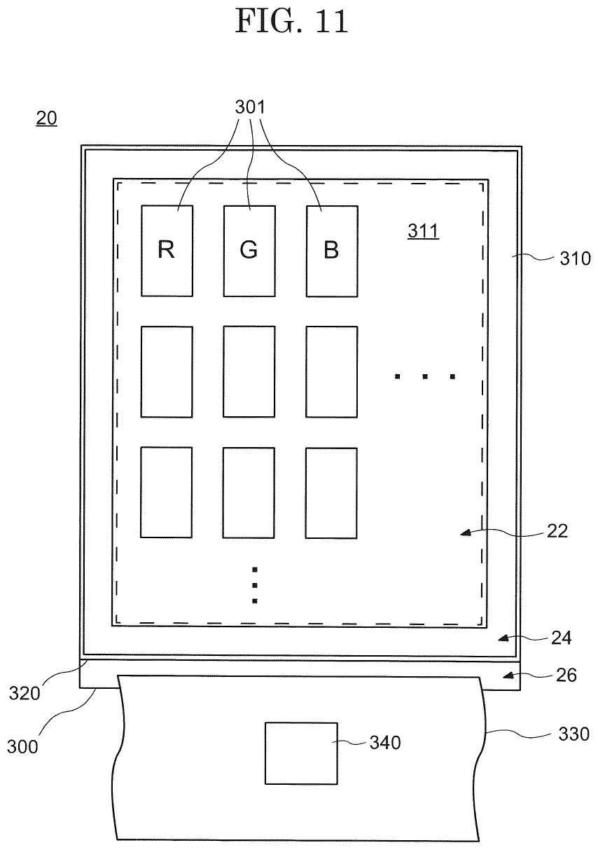

A display device using a semiconductor device according to an embodiment of the present invention will be described with reference to FIG. 11 to FIG. 15. In the embodiment shown below, a configuration in which the semiconductor device 10 described in the first embodiment described above is applied to a circuit of the liquid crystal display device will be described.

### 2-1. Outline of Display Device 20

FIG. 11 is a plan view showing an outline of a display device according to an embodiment of the present invention. As is shown in FIG. 11, the display device 20 includes an array substrate 300, a seal portion 310, a counter substrate 320, a flexible printed circuit substrate 330 (FPC 330), and an IC chip 340. The array substrate 300 and the counter substrate 320 are bonded together by the seal portion 310. A plurality of pixel circuits 301 is arranged in a matrix in a liquid crystal region 22 surrounded by the seal portion 310. The liquid crystal region 22 is a region overlapping a liquid crystal element 311, which will be described later, in a plan view.

A seal region 24 where the seal portion 310 is arranged is a region surrounding the liquid crystal region 22. The FPC 330 is arranged in a terminal region 26. The terminal region 26 is a region where the array substrate 300 is exposed from the counter substrate 320 and is arranged outside the seal region 24. Outside the seal region 24 means regions outside the region where the seal portion 310 is arranged and a region surrounded by the seal portion 310. The IC chip 340 is arranged on the FPC 330. The IC chip 340 supplies a signal for driving each pixel circuit 301.

### 2-2. Circuit Configuration of Display Device 20

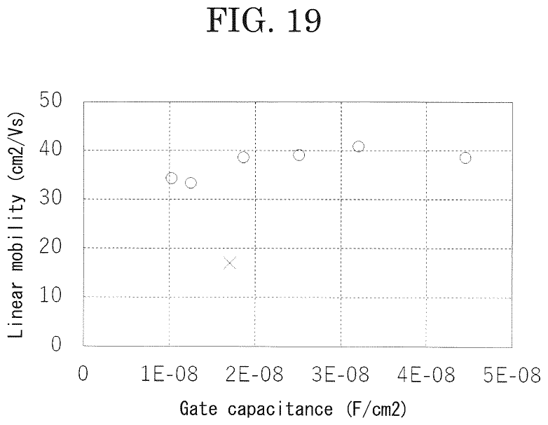

FIG. 19 is a block diagram showing a circuit configuration of a display device according to an embodiment of the present invention. As is shown in FIG. 19, a source driver circuit 302 is arranged at a position adjacent to the liquid crystal region 22 where the pixel circuit 301 is arranged in an opposite direction of a direction D3 (column direction), and a gate driver circuit 303 is arranged at a position adjacent to the liquid crystal region 22 in a direction D4 and an opposite direction of the direction D4 (row direction). The source driver circuit 302 and the gate driver circuit 303 are arranged in the seal region 24 described above. However, the region where the source driver circuit 302 and the gate driver circuit 303 are arranged is not limited to the seal region 24. The source driver circuit 302 and the gate driver circuit 303 may be arranged in any region outside the region where the pixel circuit 301 is arranged.

A source wiring 304 extends from the source driver circuit 302 in the direction D3 and is connected to the plurality of pixel circuits 301 arranged in the direction D3. A gate wiring 305 extends from the gate driver circuit 303 in the direction D4 and is connected to the plurality of pixel circuits 301 arranged in the direction D4.

A terminal portion 306 is arranged in the terminal region 26. The terminal portion 306 and the source driver circuit 302 are connected by a connection wiring 307. Similarly, the terminal portion 306 and the gate driver circuit 303 are connected by the connection wiring 307. Since the FPC 330 is connected to the terminal portion 306, an external device which is connected to the FPC 330 and the display device 20 are connected, and each pixel circuit 301 arranged in the display device 20 is driven by a signal from the external device.

The semiconductor device 10 shown in the first embodiment is used as a transistor included in the pixel circuit 301, the source driver circuit 302, and the gate driver circuit 303.

### 2-3. Pixel Circuit 301 of Display Device 20

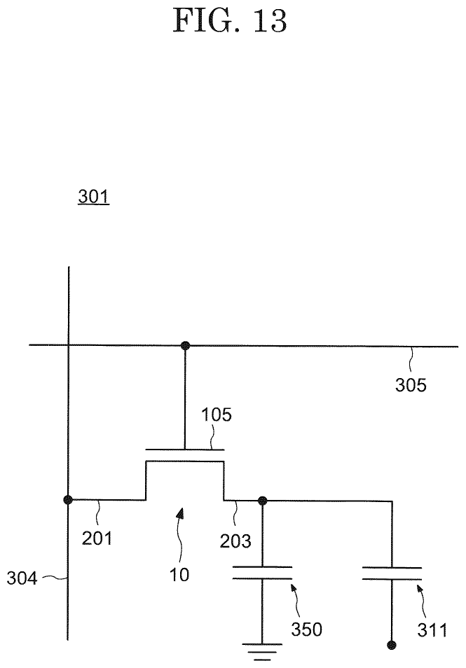

FIG. 13 is a circuit diagram showing a pixel circuit of a display device according to an embodiment of the present invention. As is shown in FIG. 13, the pixel circuit 301 includes elements such as the semiconductor device 10, a storage capacitor element 350, and the liquid crystal element 311. The semiconductor device 10 has the gate electrode 105, the source electrode 201, and the drain electrode 203. The gate electrode 105 is connected to the gate wiring 305. The source electrode 201 is connected to the source wiring 304. The drain electrode 203 is connected to the storage capacitor element 350 and the liquid crystal element 311. In the present embodiment, although an electrode indicated by “201” is referred to as a source electrode and an electrode indicated by “203” is referred to as a drain electrode for the convenience of explanation, the electrode indicated by “201” may function as a drain electrode and the electrode indicated by “203” may function as a source electrode.

### 2-4. Cross-Sectional Structure of Display Device 20

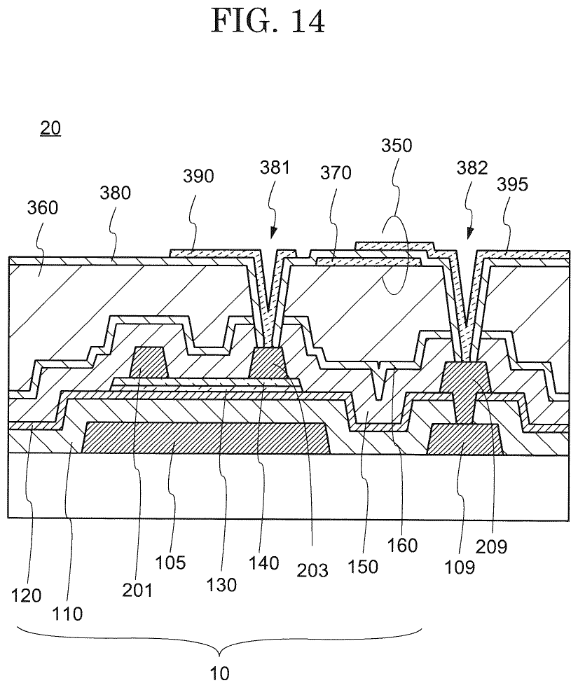

FIG. 14 is a cross-sectional view of a display device according to an embodiment of the present invention. As shown in FIG. 14, the display device 20 is a display device in which the semiconductor device 10 is used. In the present embodiment, although a configuration in which the semiconductor device 10 is used for the pixel circuit 301 is exemplified, the semiconductor device 10 may be used for a peripheral circuit including the source driver circuit 302 and the gate driver circuit 303. In the following description, since the configuration of the semiconductor device 10 is the same as that of the semiconductor device 10 shown in FIG. 1, the description thereof will be omitted.

An insulating layer 360 is arranged on the source electrode 201 and the drain electrode 203. A common electrode 370 arranged in common for the plurality of pixels is arranged on the insulating layer 360. An insulating layer 380 is arranged on the common electrode 370. Openings 381 and 382 are arranged in the insulating layers 360 and 380. A pixel electrode 390 is arranged on the insulating layer 380 and within the opening 381. The pixel electrode 390 is connected to the drain electrode 203. A electrode 395 is arranged on the insulating layer 380 and inside the opening 382. The electrode 395 configures the storage capacitor element 350 together with the common electrode 370.

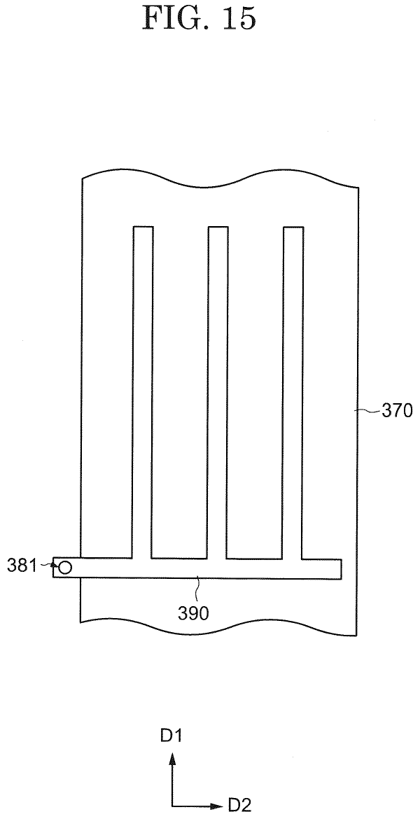

FIG. 15 is a plan view of a pixel electrode and a common electrode of a display device according to an embodiment of the present invention. As shown in FIG. 15, the common electrode 370 has an overlapping region overlapping the pixel electrode 390 in a plan view, and a non-overlapping region not overlapping the pixel electrode 390. When a voltage is supplied between the pixel electrode 390 and the common electrode 370, a horizontal electric field is formed from the pixel electrode 390 in the overlapping region toward the common electrode 370 in the non-overlapping region. A gradation of the pixel is determined by the operation of liquid crystal molecules included in the liquid crystal element 311 by the horizontal electric field.

### 3. Third Embodiment

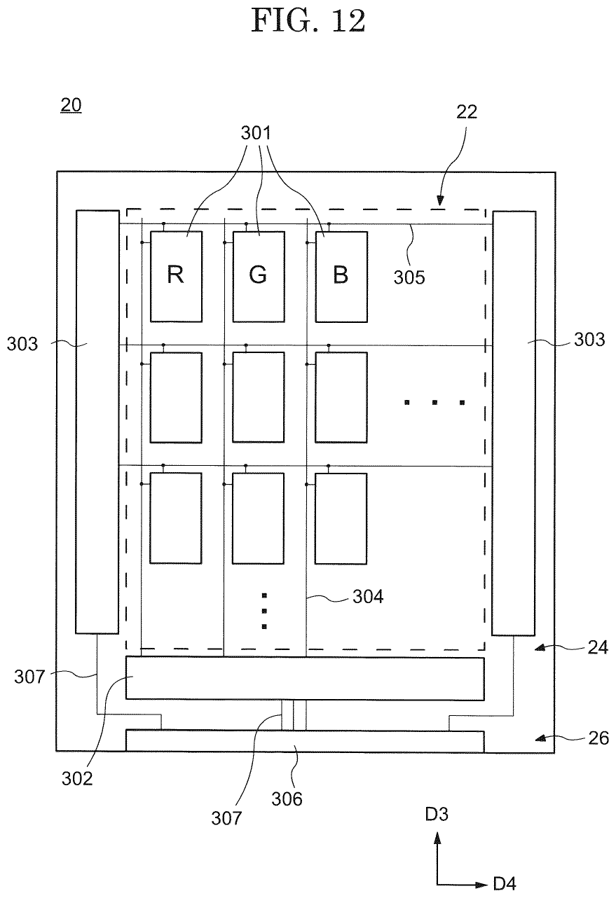

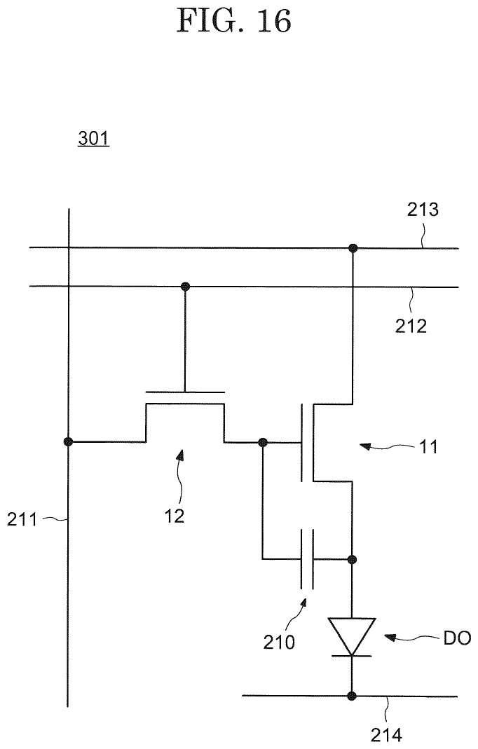

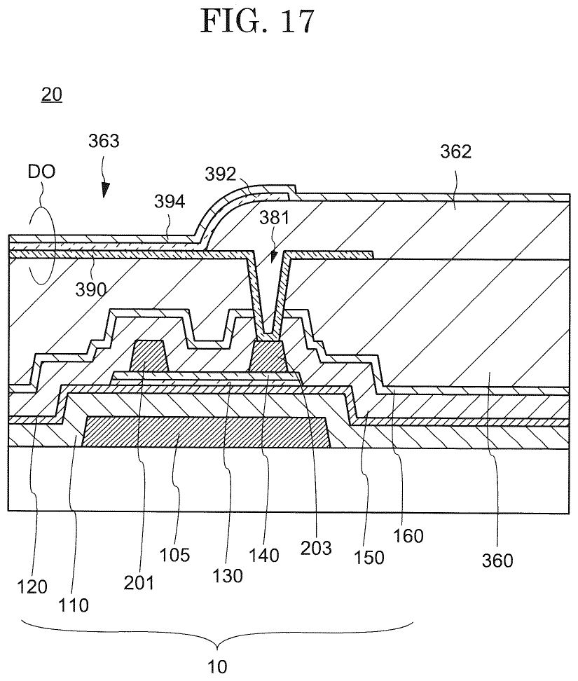

A display device using a semiconductor device according to an embodiment of the present invention will be explained with reference to FIG. 16 and FIG. 17. In the present embodiment, a configuration in which the semiconductor device 10 explained in the first embodiment is applied to a circuit of an organic EL display device will be described. Since the outline and the circuit configuration of the display device 20 are the same as those shown in FIG. 11 and FIG. 12, the description thereof will be omitted.

### 3-1. Pixel Circuit 301 of Display Device 20

FIG. 16 is a circuit diagram showing a pixel circuit of a display device according to an embodiment of the present invention. As shown in FIG. 16, the pixel circuit 301 includes elements such as a drive transistor 11, a selection transistor 12, a storage capacitor element 210, and a light-emitting element DO. The drive transistor 11 and the selection transistor 12 have the same configuration as the semiconductor device 10. The source electrode of the selection transistor 12 is connected to a signal line 211, and the gate electrode of the selection transistor 12 is connected to a gate line 212. The source electrode of the drive transistor 11 is connected to an anode power line 213, and the drain electrode of the drive transistor 11 is connected to one end of the light-emitting element DO. The gate electrode of the drive transistor 11 is connected to the drain electrode of the selection transistor 12. The storage capacitor element 210 is connected to the gate electrode and the drain electrode of the drive transistor 11. A gradation signal for determining light-emitting intensity of the light-emitting element DO is supplied to the signal line 211. A signal for selecting a pixel row in which the gradation signal described above is written is supplied to the gate line 212.

### 3-2. Cross-Sectional Structure of Display Device 20

FIG. 17 is a cross-sectional diagram of a display device according to an embodiment of the present invention. Although the configuration of the display device 20 shown in FIG. 17 is similar to the display device 20 shown in FIG. 14, the configuration above the insulating layer 360 of the display device 20 in FIG. 17 is different from the structure above the insulating layer 360 of the display device 20 in FIG. 14, and it is different in that the display device 20 in FIG. 17 does not includes structures related to the storage capacitor element 350 of the display device 20 in FIG. 14. Hereinafter, in the configuration of the display device 20 in FIG. 17, descriptions of the same configuration as the display device 20 in FIG. 14 are omitted, and differences between the two will be explained.

As shown in FIG. 17, the display device 20 has the pixel electrode 390 included in the light-emitting element DO, a light-emitting layer 392, and a common electrode 394 above the insulating layer 360. The pixel electrode 390 is arranged above the insulating layer 360 and inside the opening 381. An insulating layer 362 is arranged above the pixel electrode 390. An opening 363 is arranged in the insulating layer 362. The opening 363 corresponds to a light-emitting region. That is, the insulating layer 362 defines a pixel. The light-emitting layer 392 and the common electrode 394 are arranged above the pixel electrode 390 exposed by the opening 363. The pixel electrode 390 and the light-emitting layer 392 are individually arranged for each pixel. On the other hand, the common electrode 394 is arranged in common for the plurality of pixels. Different materials are used for the light-emitting layer 392 depending on a display color of the pixel.

In the second embodiment and third embodiment, although the configuration in which the semiconductor device explained in the first embodiment was applied to a liquid crystal display device and an organic EL display device was exemplified, the semiconductor device may be applied to display devices (for example, a self-luminous display device or an electronic paper display device other than an organic EL display device) other than these display devices. In addition, the semiconductor device described above can be applied without any particular limitation from a small sized display device to a large sized display device.

### EXAMPLES

### [Electrical Characteristics of Semiconductor Device 10]

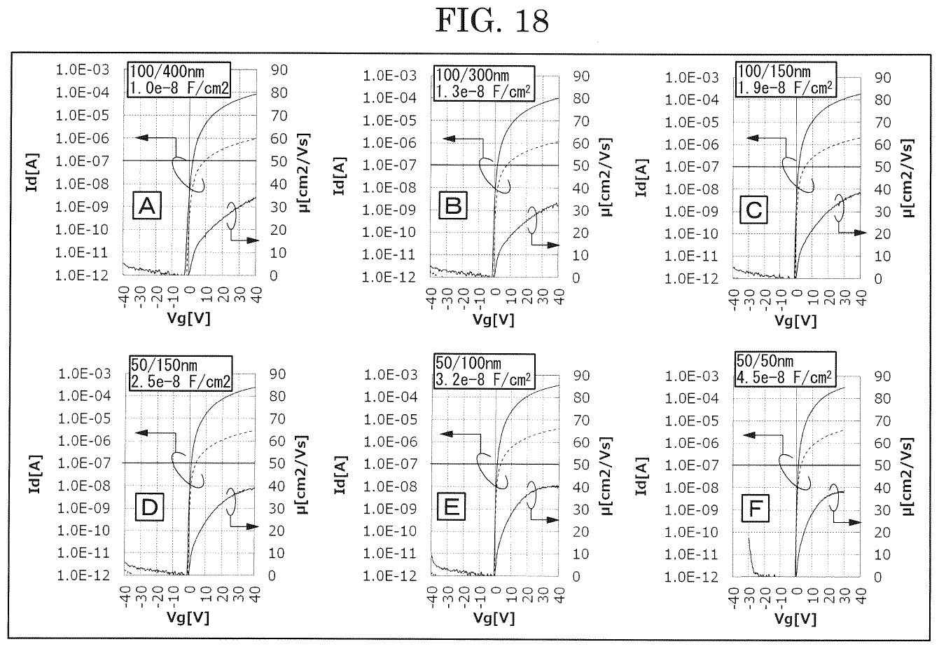

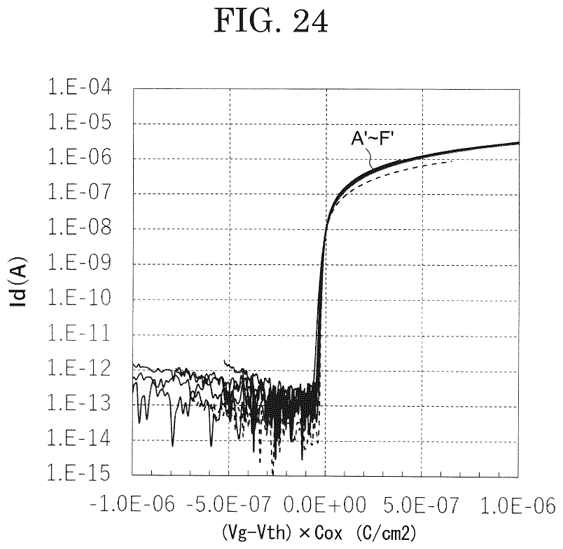

Electrical characteristics of the semiconductor device 10 according to the above embodiment will be described with reference to FIG. 18 to FIG. 26. FIG. 18 is a diagram showing electric characteristics (Id-Vg characteristics) of a semiconductor device according to an embodiment of the present invention. The respective Id-Vg characteristics shown in FIG. 18 are semi-logarithmic graphs in which the Id, which is the vertical axis, is logarithmically displayed. The measurement conditions of the electrical characteristics are as follows. In FIG. 18, the electrical characteristics of the semiconductor device 10 are shown in which the thickness of the gate insulating layers 110 and 120 is different in the semiconductor device 10 shown in FIG. 1.

### [Measurement Conditions]

CH Size of the channel region: W/L=6.0 μm/6.0 μm
Source-drain voltage: 0.1 V, 10 V
Gate voltage: −40 V to +40 V (gate voltage of property F is −30 V to +30 V)
Measurement environment: room temperature, dark room

The six electrical characteristics shown in FIG. 18 are the electrical characteristics of the semiconductor device 10 in which the thicknesses of the gate insulating layers 110 and 120 are different. That is, the semiconductor device 10 exhibiting these electrical characteristics has a different gate capacitance Cox. In the present embodiment, silicon nitride is used as the gate insulating layer 110, and silicon oxide is used as the gate insulating layer 120. The thickness of silicon oxide/silicon nitride is indicated in the figure. The thicknesses are silicon oxide/silicon nitride=100/400 nm (characteristic A), 100/300 nm (characteristic B), and 100/150 nm (characteristic C) from the upper left to the right in FIG. 18. Similarly, the thicknesses are silicon oxide/silicon nitride=50/150 nm (characteristic D), 50/100 nm (characteristic E), and 50/50 nm (characteristic F) from the lower left to the right in FIG. 18.

The gate capacitance Cox in each thickness condition is indicated in FIG. 18. The gate capacitance Cox is 1.0 e-8 [F/cm²] (characteristic A), 1.3 e-8 [F/cm²] (characteristic B), and 1.9 e-8 [F/cm²] (characteristic C) from the upper left to the right in FIG. 18. Similarly, the gate capacitance Cox is 2.5 e-8 [F/cm²] (characteristic D), 3.2 e-8 [F/cm²] (characteristic E), and 4.5 e-8 [F/cm²] (characteristic F) from the lower left to the right in FIG. 18. The gate capacitance Cox was calculated using 6.5 as the relative permittivity of silicon nitride and 4.1 as the relative permittivity of silicon oxide.

The horizontal line of the solid line shown in FIG. 18 is shown at the position of the scale where the drain current Id is 10⁻⁷ [A], and the mobility is 50 [cm²/Vs]. The drain current Id varies by one digit for each scale. The mobility varies by 10 [cm²/Vs] for each scale. The vertical line of the solid line shown in each graph of FIG. 18 is shown at the position of the scale where the gate voltage is 0 [V]. The gate voltage varies by 10 [V] for each scale.

In each graph of FIG. 18, the left-pointing arrows indicate the Id-Vg characteristics of the semiconductor device 10. Two types of Id-Vg characteristics are displayed. Among the two types of Id-Vg characteristics, an Id-Vd characteristic (solid line) having a relatively large current is a characteristic when the drain voltage is 10 V, and an Id-Vg characteristic (dotted line) having a relatively small current is a characteristic when the drain voltage is 0.1 V. In each graph of FIG. 18, the right-pointing arrows indicate the mobility (linear mobility) of the semiconductor device 10 calculated from the Id-Vg characteristics when the drain-voltage Vd is 0.1 V. As shown in FIG. 18, good electrical characteristics without any particular abnormality are obtained under most conditions, and the linear mobility is 30 [cm²/Vs] or more.

In addition, in the semiconductor device 10 where silicon oxide/silicon nitride=50/50 nm, the voltage applied to the gate electrode 105 is −30 V to +30 V because the semiconductor device 10 is destroyed when a voltage higher than +30 V or lower than −30 V is applied to the gate electrode 105.

FIG. 19 is a diagram showing the linear mobility of a semiconductor device according to an embodiment of the present invention. The linear mobility shown in FIG. 19 is the highest mobility obtained from the Id-Vg characteristics when the drain voltage Vd shown in FIG. 18 is 0.1 V. The plot indicated by “o” in FIG. 19 indicates the mobility of the semiconductor device 10 according to the first embodiment. The plot indicated by “x” indicates the mobility of the conventional semiconductor device as reference data.

In the semiconductor device 10 according to the first embodiment, the linear mobility tends to be larger as the gate capacitance Cox becomes larger. In both cases, the linear mobility of the semiconductor device 10 is larger than the linear mobility of the conventional semiconductor device.

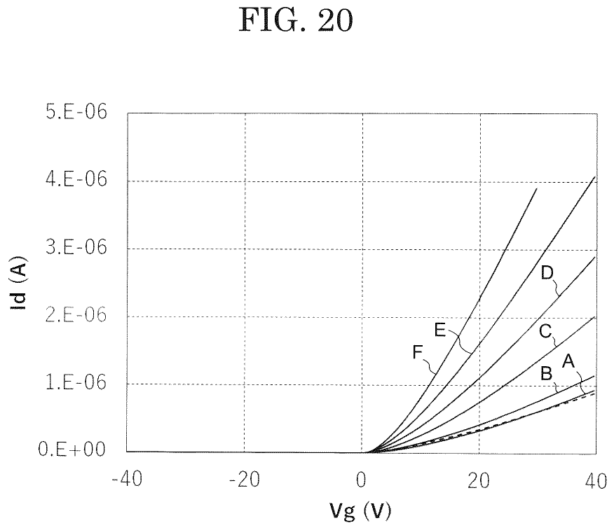

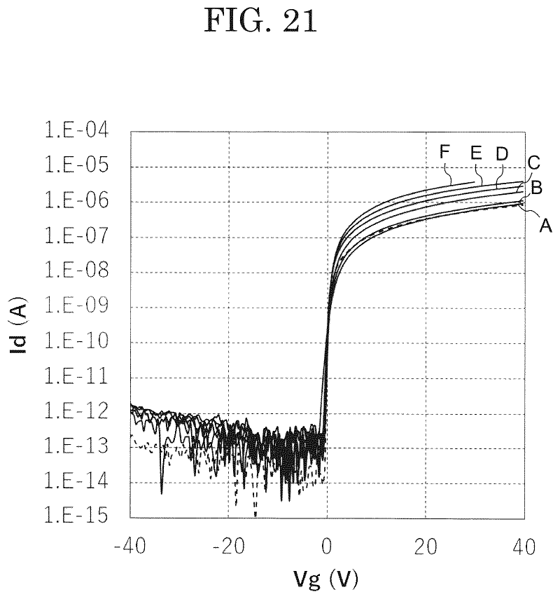

FIG. 20 and FIG. 21 are diagrams showing the dependency of the gate capacitance in the electrical characteristics of a semiconductor device according to an embodiment of the present invention. FIG. 20 is a linear graph in which the drain current Id (vertical axis) is linearly displayed. FIG. 21 is a semi-logarithmic graph in which the drain current Id (vertical axis) is logarithmically displayed. Among the Id-Vg characteristics shown in FIG. 20 and FIG. 21, the characteristics A to F indicated by solid lines are the characteristics of the semiconductor device 10 according to the first embodiment. In FIG. 20 and FIG. 21, the characteristic indicated by a dotted line (substantially overlapping the characteristic A) is a characteristic (conventional characteristic) of the conventional semiconductor device. As shown in FIG. 20 and FIG. 21, the smaller the thicknesses of the gate insulating layers 110 and 120 (the larger the gate capacitance Cox), the steeper the rise of the Id-Vg characteristics and the larger current.

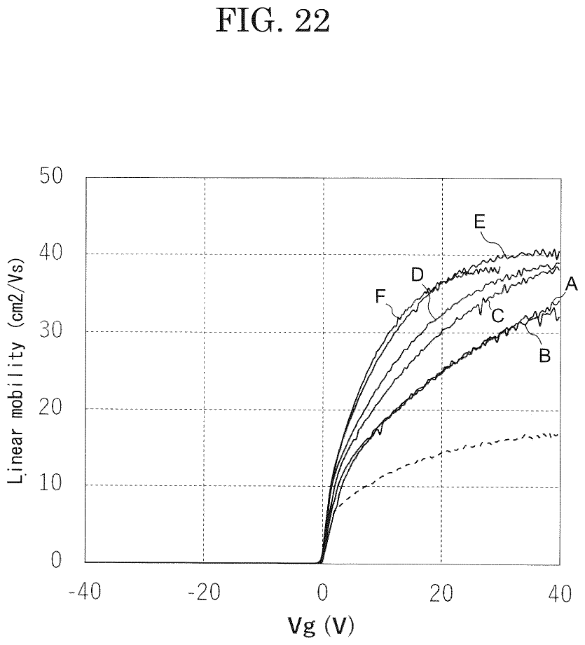

FIG. 22 is a diagram showing the dependency of gate capacitance in linear mobility of a semiconductor device according to an embodiment of the present invention. As shown in FIG. 22, the linear mobility shows the same tendency as the drain current Id in the Id-Vg characteristics. The linear mobility tends to be smaller as the thicknesses of the gate insulating layers 110 and 120 are larger, and the linear mobility tends to be larger as the thickness of the gate insulating layers 110 and 120 is smaller. In both cases, the linear mobility of the semiconductor device 10 is larger than the linear mobility of the semiconductor device using the conventional oxide semiconductor (dotted line).

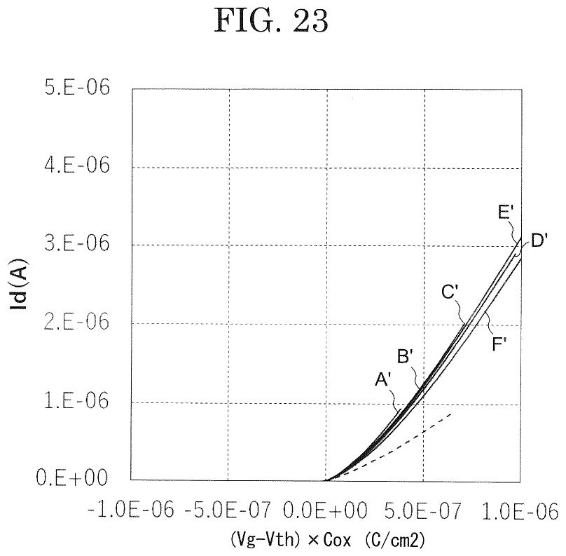

However, as described in the first embodiment, the above-described Id-Vg characteristics reflect the effect caused by defects formed in the oxide semiconductor layer and effect on the mobility by the gate capacitance Cox. Therefore, in order to reduce these effects, the above-described Id-Vg characteristics were normalized by the threshold voltage Vth and the gate capacitance Cox. The results are shown in FIG. 23 to FIG. 25. Specifically, the Id-Vg characteristics and the linear mobility shown in FIG. 23 to FIG. 25 were obtained by converting the horizontal axis from “gate voltage Vg” to “(gate voltage Vg−threshold voltage Vth)×gate capacitance Cox [(Vg−Vth)×Cox (C/cm²)” with respect to FIG. 20 to FIG. 22. Characteristics A′ to F′ in FIG. 23 to FIG. 25 correspond to the characteristics A to F in FIG. 20 to FIG. 22.

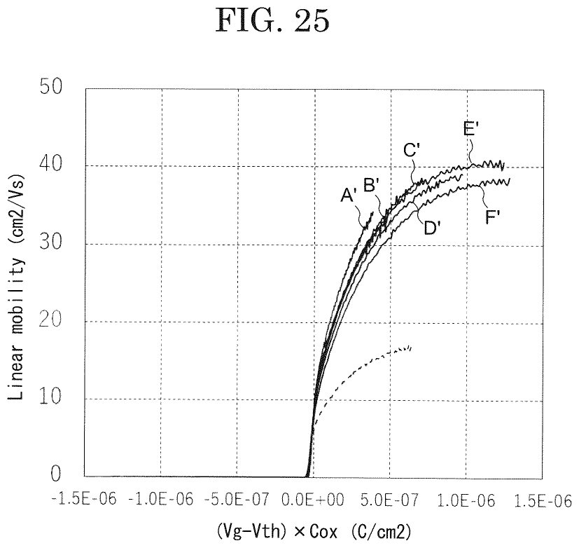

As shown in FIG. 23 to FIG. 25, by performing the normalization as described above, the effect of the gate capacitance Cox becomes small, the difference between the characteristics A′ to F′ becomes small in the Id-Vg characteristics and the linear mobility, and the difference between the characteristics A′ to F′ and the conventional characteristics (dotted line) becomes remarkable. As shown in FIG. 25, the linear mobility in the normalized Id-Vg characteristics is larger than 20 cm²/Vs, 25 cm²/Vs, or 30 cm²/Vs when (Vg−Vth)× Cox=5×10⁻⁷ C/cm², for any of the characteristics A′ to F′. Furthermore, the linear mobility is larger than 30 cm²/Vs or 35 cm²/Vs when (Vg−Vth)× Cox=1×10⁻⁶ C/cm²). The above linear mobility value is a value that conventional characteristics (dotted line) cannot achieve.

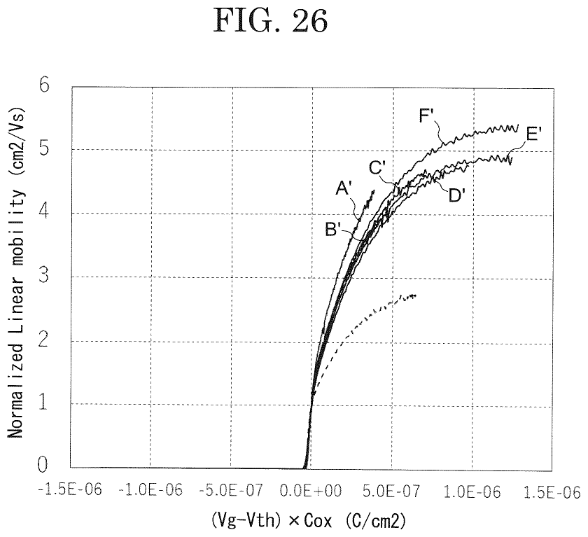

FIG. 26 is a diagram showing the dependency of gate capacitance in a normalized linear mobility of a semiconductor device according to an embodiment of the present invention. As described above, the normalized linear mobility is the mobility obtained by normalizing the linear mobility with (Vg−Vth)×Cox as the horizontal axis by the linear mobility in Vg=Vth. The normalized linear mobility shown in FIG. 26 shows the same behavior as the linear mobility shown in FIG. 25. The normalized linear mobility is larger than 3.0, 3.5, or 4.0 when (Vg−Vth)×Cox=5×10⁻⁷ C/cm² for any of the characteristics A′ to F′. Furthermore, the normalized linear mobility is larger than 4.0 or 4.5 when (Vg−Vth)×Cox=1×10⁻⁶ C/cm². The normalized linear mobility values described above are values that conventional characteristics cannot achieve.

As described above, in the semiconductor device 10 according to the first embodiment, the linear mobility and the normalized linear mobility that cannot be achieved by the conventional semiconductor device can be obtained regardless of the gate capacitance Cox associated with the thicknesses of the gate insulating layers 110 and 120.

Each of the embodiments described above as an embodiment of the present invention can be appropriately combined and implemented as long as no contradiction is caused. Furthermore, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a gate electrode;
a gate insulating layer above the gate electrode;
a metal oxide layer containing aluminum as a main component above the gate insulating layer;
an oxide semiconductor layer having a polycrystalline structure above the metal oxide layer;
a source electrode and a drain electrode contacting the oxide semiconductor layer from above the oxide semiconductor layer; and
an insulating layer above the source electrode and the drain electrode,
wherein
a linear mobility of the semiconductor device is larger than 20 cm²/Vs when (Vg−Vth)×Cox=5×10⁻⁷ C/cm², in the case where
the Vg is a voltage supplied to the gate electrode, the Vth is a threshold voltage of the semiconductor device, and the Cox is an electrostatic capacitance of the gate insulating layer sandwiched by the gate electrode and the oxide semiconductor layer.

2. The semiconductor device according to claim 1, wherein the linear mobility is larger than 30 cm²/Vs when (Vg−Vth)×Cox=1×10⁻⁶ C/cm².

3. The semiconductor device according to claim 1, wherein
the Vth is a voltage Vg in the case where the semiconductor device flows a current of W/Lx 10 nA in a condition that a voltage between the source electrode and the drain electrode is 0.1 V,
the L is a length of a channel region in a first direction connecting the source electrode and the drain electrode,
the W is a width of the channel region in a second direction orthogonal to the first direction, and
the channel region is a region where the gate electrode overlaps the oxide semiconductor layer and is sandwiched between the source electrode and the drain electrode.

4. The semiconductor device according to claim 1, wherein
the linear mobility is calculated based on an Id-Vg characteristic in the case where a voltage between the source electrode and the drain electrode is 0.1 V.

5. A semiconductor device comprising:
a gate electrode;
a gate insulating layer above the gate electrode;
a metal oxide layer containing aluminum as a main component above the gate insulating layer;
an oxide semiconductor layer having a polycrystalline structure above the metal oxide layer;
a source electrode and a drain electrode contacting the oxide semiconductor layer from above the oxide semiconductor layer; and
an insulating layer above the source electrode and the drain electrode,
wherein
a linear mobility of the semiconductor device is larger than 30 cm²/Vs when (Vg−Vth)×Cox=1×10⁻⁶ C/cm², in the case where
the Vg is a voltage supplied to the gate electrode, the Vth is a threshold voltage of the semiconductor device, and the Cox is an electrostatic capacitance of the gate insulating layer sandwiched between the gate electrode and the oxide semiconductor layer.

6. A semiconductor device comprising:
a gate electrode;
a gate insulating layer above the gate electrode;
a metal oxide layer containing aluminum as a main component above the gate insulating layer;
an oxide semiconductor layer having a polycrystalline structure above the metal oxide layer;
a source electrode and a drain electrode contacting the oxide semiconductor layer from above the oxide semiconductor layer; and
an insulating layer above the source electrode and the drain electrode,
wherein
a normalized linear mobility normalized by a linear mobility of the semiconductor device in a condition of Vg=Vth is larger than 3.0 when (Vg−Vth)× Cox=5×10⁻⁷ C/cm², in the case where
the Vg is a voltage supplied to the gate electrode, the Vth is a threshold voltage of the semiconductor device, and the Cox is an electrostatic capacitance of the gate insulating layer sandwiched between the gate electrode and the oxide semiconductor layer.

7. The semiconductor device according to claim 6, wherein the normalized linear mobility is larger than 4.0 when (Vg−Vth)×Cox=1×10−6 C/cm².

8. The semiconductor device according to claim 6, wherein
the Vth is a voltage Vg in the case where the semiconductor device flows a current of W/Lx 10 nA in a condition that a voltage between the source electrode and the drain electrode is 0.1 V,
the L is a length of a channel region in a first direction connecting the source electrode and the drain electrode,
the W is a width of the channel region in a second direction orthogonal to the first direction, and
the channel region is a region where the gate electrode overlaps the oxide semiconductor layer and is sandwiched between the source electrode and the drain electrode.

9. The semiconductor device according to claim 6, wherein
the linear mobility is calculated based on an Id-Vg characteristic in the case where a voltage between the source electrode and the drain electrode is 0.1 V.
